(19) United States
(12) Patent Application Publication
(10) Pub. No.: US 2007/0072311 A1
(43) Pub. Date: Mar. 29, 2007

(54) Interconnect for a GMR Stack Layer and an Underlying Conducting Layer

(75) Inventors: Vicki Wilson, St. Paul, MN (US); Guoqing Zhan, St. Paul, MN (US); Ray Buske, St. Paul, MN (US); James Chyi Lai, St. Paul, MN (US)

Correspondence Address: THOMAS, KAYDEN, HORSTEMEYER & RISLEY, LLP, 100 GALLERIA PARKWAY, NW, STE 1750, ATLANTA, GA, 30339-5948, US

(73) Assignee: NORTHERN LIGHTS SEMICONDUCTOR CORP., St. Paul, MN (US)

(21) Appl. No.: 11/533,077

(22) Filed: Sep. 19, 2006

Related U.S. Application Data
(60) Provisional application No. 60/721,359, filed on Sep. 28, 2005.

(51) Int. Cl. H01L 21/00; G11C 11/00; H01L 21/8244

(52) U.S. Cl. 438/3; 365/159; 438/238

(57) ABSTRACT

Metal plugs located in a planar dielectric layer, under a GMR stack layer, are used to connect the nonmagnetic conducting layer of the GMR stack layer and a conducting layer under the planar dielectric layer.

### CROSS-REFERENCE TO RELATED APPLICATION

This application claims the priority benefit of provisional application Ser. No. 60/721,359, filed Sep. 28, 2005, the full disclosure of which is incorporated herein by reference.

### BACKGROUND

1. Field of Invention

The present invention relates to a static memory. More particularly, the present invention relates to a magnetoresistive random access memory (MRAM).

2. Description of Related Art

MRAM is a type of non-volatile memory with fast programming time and high density. A MRAM cell of giant magnetoresistance (GMR) type has two ferromagnetic layers separated by a nonmagnetic conducting layer. Information is stored as directions of magnetization vectors in the two ferromagnetic layers.

The resistance of the nonmagnetic layer between the two ferromagnetic layers indicates a minimum value when the magnetization vectors of the two ferromagnetic layers point in substantially the same direction. On the other hand, the resistance of the nonmagnetic layer between the two ferromagnetic layers indicates a maximum value when the magnetization vectors of the two ferromagnetic layers point in substantially opposite directions. Accordingly, a detection of changes in resistance allows information being stored in the MRAM cell.

In conventional MRAM architecture, MRAM cells are placed on intersections of bit lines and word lines. The bit lines and word lines connect to the peripheral circuits and/or logic circuits through metal lines and/or plugs disposed on the peripheral area surrounding the MRAM area. Hence, the integration density is limited.

### SUMMARY

Metal plugs located in a planar dielectric layer, under a GMR stack layer, are used to connect the nonmagnetic conducting layer of the GMR stack layer and a conducting layer under the planar dielectric layer.

### BRIEF DESCRIPTION OF THE DRAWINGS

The invention can be more fully understood by reading the following detailed description of the preferred embodiment, with reference made to the accompanying drawings as follows:

FIGS. 1A-1C are cross-sectional diagrams showing a method of fabricating an interconnect structure according to an embodiment of this invention.

### DETAILED DESCRIPTION

Reference will now be made in detail to the present preferred embodiments of the invention, examples of which are illustrated in the accompanying drawings.

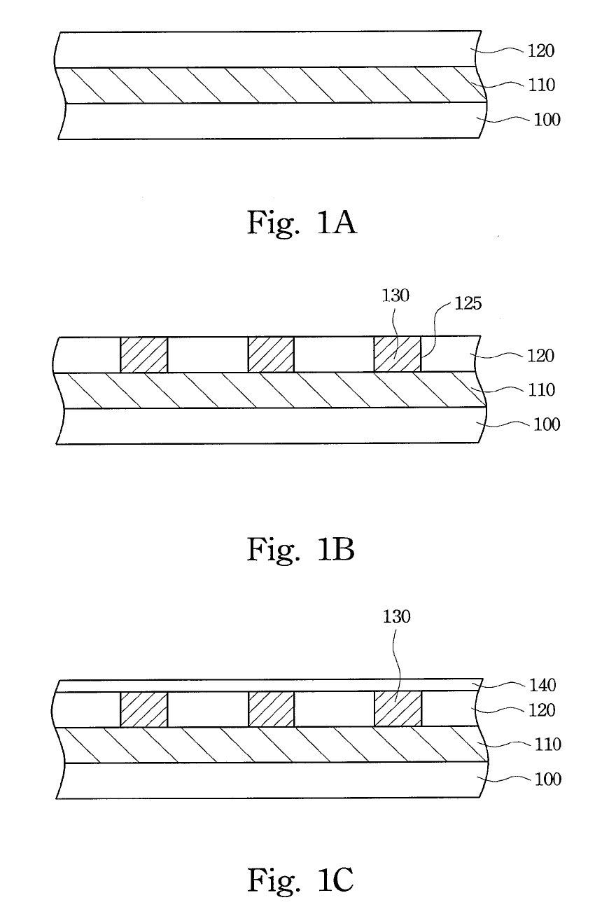

FIGS. 1A-1C are cross-sectional diagrams showing a method of fabricating an interconnect structure according to an embodiment of this invention. In FIG. 1A, a substrate 100 having a patterned conducting layer 110 thereon is provided. Then, a planar dielectric layer 120 is formed on the conducting layer 110.

The patterned conducting layer 110 represents a conducting circuit. A material of the conducting layer 110 can be any conductive material, such as metal or metal alloy. For example, Cu or Al—Cu alloy are usually used to fabricate interconnects in semiconductor integrated circuits. A material of the dielectric layer 120 can be, for example, silicon oxide, silicon nitride, silicon oxynitride, metal oxide, or other usable dielectric materials. The thickness of the dielectric layer is about 1500-3500 Angstroms.

In FIG. 1B, the dielectric layer 120 is patterned, such as a photolithography process and an etching process performed sequentially, to form openings 125 therein. After depositing a metal in the openings 125 and on the dielectric layer 120, a planarization process, such as chemical mechanical polishing (CMP), is performed to planarized the metal layer until the dielectric layer 120 is exposed. Thus, plugs 130 are formed in the openings 125. A material of the plugs 130 can be, for example, tungsten or other conductive metals.

In FIG. 1C, a GMR stack layer 140, are deposited on the dielectric layer 120 and the tungsten plugs 130. The GMR stack layer 140 comprises a first ferromagnetic layer, a nonmagnetic conducting layer, and a second ferromagnetic layer, wherein the nonmagnetic conducting layer, such as a Cu layer, is directly contact to the plugs 130 to build electrical connection.

According the embodiment provided above, the plugs are located in the dielectric layer below the GMR stack layer to connect the underlying conducting circuit. Hence, more options in layout design utilizing the GMR stack layer are allowed. Moreover, since the dielectric layer is thin, the step coverage of metal deposition is good.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method of fabricating an interconnect for a GMR stack layer, comprising:
forming a planar dielectric layer on a patterned conducting layer, which is on a substrate;
patterning the dielectric layer to form openings therein;
forming metal plugs in the openings to electrically connect the patterned conducting layer; and
forming a GMR stack layer on the metal plugs and the dielectric layer, wherein a nonmagnetic conducting layer of the GMR stack layer directly connected to the metal plugs.

2. The method of claim 1, wherein the dielectric layer is silicon oxide, silicon nitride, or silicon oxynitride.

3. The method of claim 1, wherein the metal plugs are tungsten plugs.

4. The method of claim 1, wherein the nonmagnetic conducting layer is a Cu layer.

5. An interconnect for a GMR stack layer and a underlying conducting layer, comprising:
a patterned conducting layer on a substrate;
a planar dielectric layer on the conducting layer;
metal plugs, which are electrically connecting to the patterned conducting layer, located in the dielectric layer; and
a GMR stack layer on the metal plugs and the dielectric layer, wherein a nonmagnetic conducting layer of the GMR stack layer directly connected to the metal plugs.

6. The interconnect of claim 4, wherein the dielectric layer is silicon oxide, silicon nitride, or silicon oxynitride.

7. The interconnect of claim 4, wherein the metal plugs are tungsten plugs.

8. The interconnect of claim 4, wherein the nonmagnetic conducting layer is a Cu layer.
